(19) United States
(12) Patent Application Publication
(10) Pub. No.: US 2015/0245485 A1
(43) Pub. Date: Aug. 27, 2015

(54) PRINTED WIRING BOARD AND METHOD FOR MANUFACTURING PRINTED WIRING BOARD

(71) Applicant: IBIDEN CO., LTD., Ogaki-shi (JP)

(72) Inventors: Nobuya TAKAHASHI, Ogaki-shi (JP); Shigeru YAMADA, Ogaki-shi (JP); Takashi KARIYA, Ogaki-shi (JP)

(73) Assignee: IBIDEN CO., LTD., Ogaki-shi (JP)

(21) Appl. No.: 14/628,477

(22) Filed: Feb. 23, 2015

(30) Foreign Application Priority Data
Feb. 24, 2014 (JP) 2014-032712

(51) Int. Cl. H05K 1/11; H05K 3/18; H05K 3/30

(52) U.S. Cl. CPC H05K 1/113; H05K 3/305; H05K 3/188; H05K 2203/0723

(57) ABSTRACT

A printed wiring board includes a first insulating layer, a first conductor layer formed on a surface of the first insulating layer and including first pads, and a wiring structure including a second conductor layer formed on the first insulating layer, a second insulating layer laminated on the second conductor layer, a third conductor layer formed on the second insulating layer, and formed through the second insulating layer. The second conductor layer includes second pads formed on the first insulating layer, the third conductor layer includes third pads formed on the second insulating layer, the via conductors are positioned such that the via conductors are connecting the second pads and the third conductor layer, and the wiring structure is formed such that the second conductor layer and third conductor layer are not electrically connected to the first conductor layer.

### CROSS-REFERENCE TO RELATED APPLICATIONS

The present application is based upon and claims the benefit of priority to Japanese Patent Application No. 2014-032712, filed Feb. 24, 2014, the entire contents of which are incorporated herein by reference.

### BACKGROUND OF THE INVENTION

1. Field of the Invention

The present invention relates to a printed wiring board having multiple electronic components installed therein, and to a method for manufacturing the printed wiring board.

2. Description of Background Art

Japanese Patent Laid-open Publication No. 2011-211194 describes a structure in which a heat-resistant substrate is accommodated in a cavity provided to a printed wiring board and in which a connection wiring is provided on the heat-resistant substrate between a CPU and a memory. The entire contents of this publication are incorporated herein by reference.

### SUMMARY OF THE INVENTION

According to one aspect of the present invention, a printed wiring board includes a first insulating layer, a first conductor layer formed on a surface of the first insulating layer and including first pads, and a wiring structure including a second conductor layer formed on the first insulating layer, a second insulating layer laminated on the second conductor layer, a third conductor layer formed on the second insulating layer, and formed through the second insulating layer. The second conductor layer includes second pads formed on the first insulating layer, the third conductor layer includes third pads formed on the second insulating layer, the via conductors are positioned such that the via conductors are connecting the second pads and the third conductor layer, and the wiring structure is formed such that the second conductor layer and third conductor layer are not electrically connected to the first conductor layer.

According to another aspect of the present invention, a manufacturing method for a printed wiring board includes forming a first conductor layer on a surface of a first insulating layer, and forming a wiring structure on the surface of the first insulating layer such that the wiring structure has a second conductor layer on the first insulating layer, a second insulating layer laminated on the second conductor layer, a third conductor layer formed on the second insulating layer, and via conductors formed through the second insulating layer. The second conductor layer is formed to include second pads on the first insulating layer, the third conductor layer is formed to include third pads formed on the second insulating layer, the via conductors are positioned such that the via conductors are connecting the second pads and the third conductor layer, and the wiring structure is formed such that the second conductor layer and third conductor layer are not electrically connected to the first conductor layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a printed wiring board according to a first embodiment of the present invention;

FIG. 2 is a cross-sectional view of the printed wiring board according to the first embodiment;

FIG. 3A is a cross-sectional, enlarged view of a wiring structure demarcated by a dashed line in FIG. 1;

FIG. 3B is a plan view of the wiring structure;

FIG. 3C is an enlarged view of a portion in FIG. 3A demarcated by an ellipse (C);

FIG. 4A-4D are a manufacturing flow chart for the printed wiring board according to the first embodiment;

FIG. 5A-5C are a manufacturing flow chart for the printed wiring board according to the first embodiment;

FIG. 6A-6C are a manufacturing flow chart for the printed wiring board according to the first embodiment;

FIG. 7A-7C are a manufacturing flow chart for the printed wiring board according to the first embodiment;

FIG. 8A-8C are a manufacturing flow chart for the printed wiring board according to the first embodiment;

FIG. 9A-9C are a manufacturing flow chart for the printed wiring board according to the first embodiment;

FIG. 10A is a plan view of the printed wiring board prior to installation of an IC chip;

FIG. 10B is a plan view of the printed wiring board after the IC chip has been installed;

FIG. 11A is a plan view of a first conductor layer;

FIG. 11B is a plan view of a third conductor layer;

FIG. 11C is a plan view of a second conductor layer; and

FIG. 12A-12C are a manufacturing flow chart for a printed wiring board according to a second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

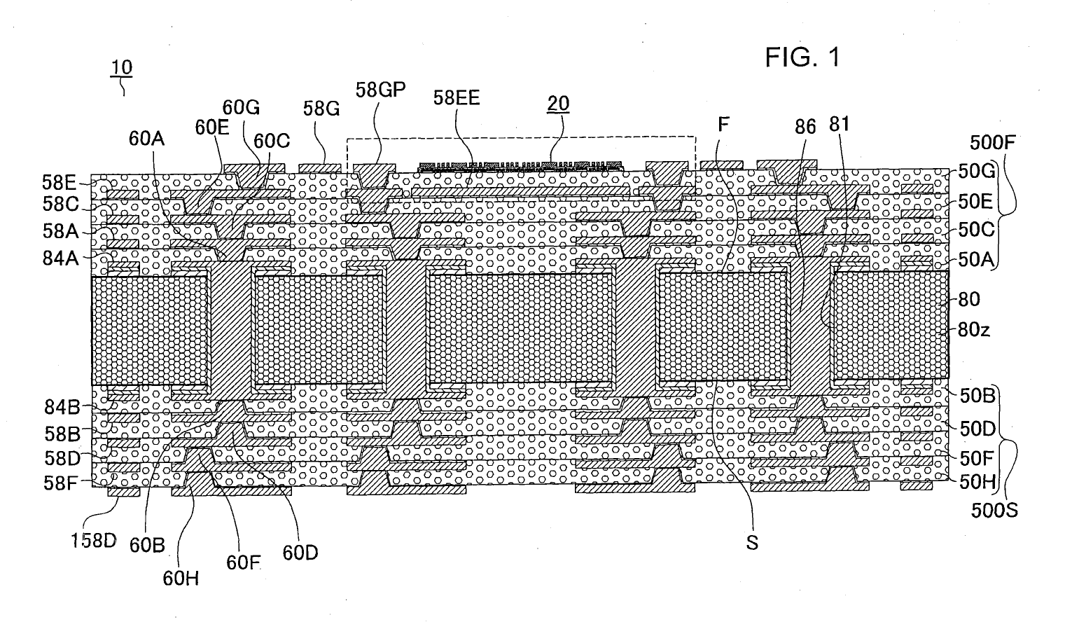

FIG. 1 is a cross-sectional view of a printed wiring board (10) according to a first embodiment of the present invention. The printed wiring board (10) includes a core substrate (80). The core substrate (80) is formed by an insulating substrate material (80z) having a first surface (F) and a second surface (S) on the opposite side from the first surface; a conductor layer (84A) on the first surface of the insulating substrate material; a conductor layer (84B) on the second surface of the insulating substrate material; and a through-hole conductor (86) connecting the conductor layer (84A) and the conductor layer (84B). The through-hole conductor (86) is formed by filling, with a plating film, an interior of a through-hole (81) formed in the insulating substrate material.

The first surface of the core substrate and the first surface of the insulating substrate material are the same surface, and the second surface of the core substrate and the second surface of the insulating substrate material (insulating substrate) are the same surface. A first build-up layer (500F) is formed on the first surface (F) of the core substrate (80). The first build-up layer (500F) includes four interlayer resin insulating layers (50A, 50C, 50E, 50G) formed on the first surface (F) of the core substrate (80).

A conductor layer (58A) is formed on the fourth interlayer resin insulating layer (50A). The third interlayer resin insulating layer (50C) is formed on the fourth interlayer resin insulating layer (50A) and the conductor layer (58A). A conductor layer (58C) is formed on the third interlayer resin insulating layer (50C). The second interlayer resin insulating layer (50E) is formed on the third interlayer resin insulating layer (50C) and the conductor layer (58C). A conductor layer (58E) is formed on the second interlayer resin insulating layer (50E). The first interlayer resin insulating layer (50G) is formed on the second interlayer resin insulating layer (50E) and the conductor layer (58E). A first conductor layer (58G) is formed on the first interlayer resin insulating layer (50G). The first build-up layer includes the first conductor layer (58G), the conductor layer (58E), the conductor layer (58C), and the conductor layer (58A). The conductor layers (84A, 58A, 58C, 58E, 58G) on different layers are connected by via conductors (60A, 60C, 60E, 60G) which run through the interlayer resin insulating layers.

A second build-up layer (500S) is formed on the second surface (S) of the core substrate (30). A layer structure of the second build-up layer (500S) is similar to that of the first build-up layer. The second build-up layer (500S) includes four interlayer resin insulating layers (50B, 50D, 50F, 50H). The second build-up layer is formed by the interlayer resin insulating layers (50B, 50D, 50F 50H) and by conductor layers (84B, 58B, 58D, 58F, 58H), the interlayer resin insulating layers and conductor layers being alternatingly laminated, and the conductor layers of different layers are connected by via conductors (60B, 60D, 60F, 60H), which are formed in the interlayer resin insulating layers.

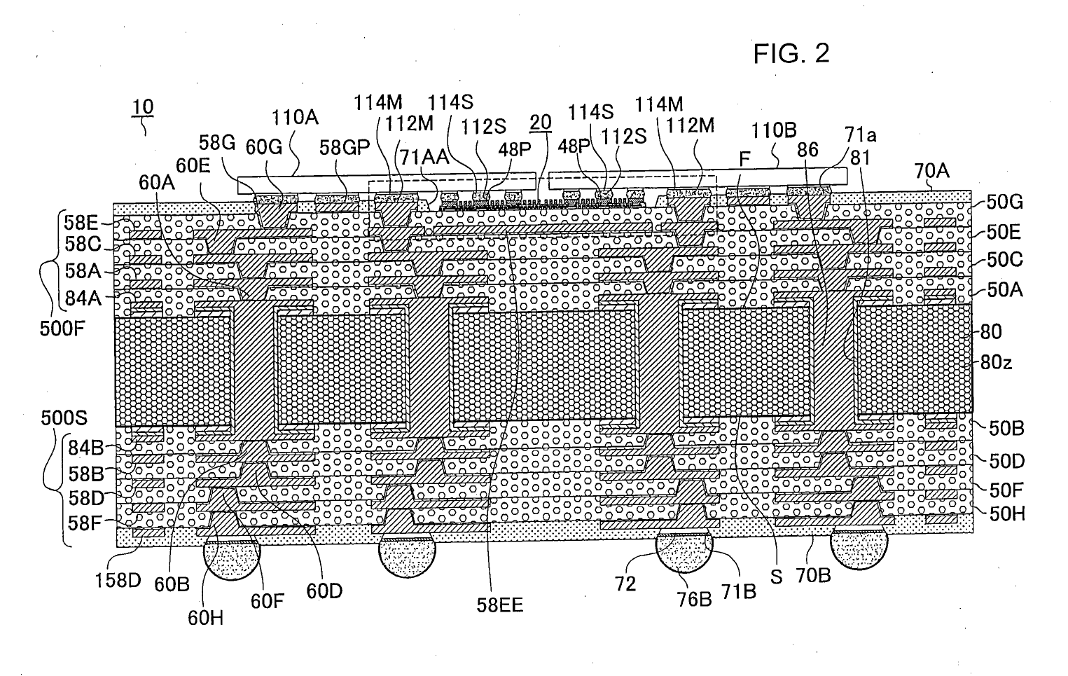

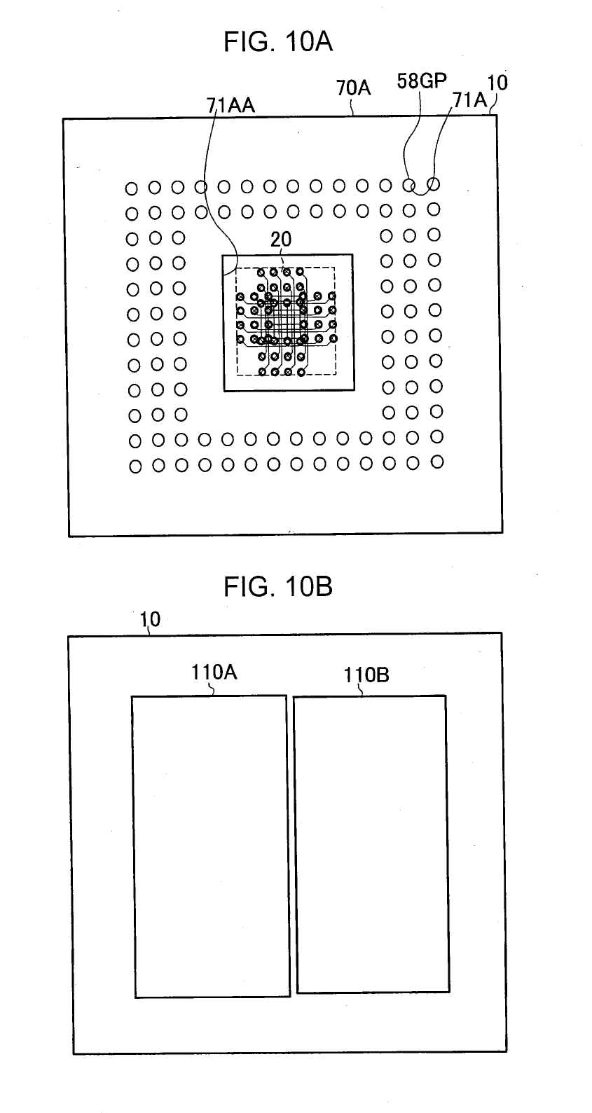

FIG. 2 is a cross-sectional view of a state where solder resist layers (70A, 70B) are respectively formed on the build-up layers (500F, 500S) of the printed wiring board, and a first IC chip (110A) and second IC chip (110B) have been installed. FIG. 10A is a plan view of the printed wiring board (10) prior to installation of the IC chips, and FIG. 10B is a plan view of the printed wiring board (10) after the first IC chip (110A) and the second IC chip (110B) have been installed. The first IC chip (110A) forms a digital portion, the second IC chip (110B) forms an analog portion, and the first IC chip (110A) and the second IC chip (110B) together serve a processor function.

As shown in FIG. 2, the first conductor layer (58G) is formed on the first interlayer resin insulating layer (outermost interlayer insulating layer) (50G). The solder resist layer (70A) is formed on the first interlayer resin insulating layer (50G), and an opening (71A) in the solder resist layer (70A) exposes a first pad (58GP). A first terminal (114M) of the IC chip is connected to the first pad (58GP) via a first solder bump (112M). The first pad (58GP) includes the first conductor layer (58G). The solder resist layer (70B) is formed on the second build-up layer (500S), and a BGA bump (76B) is formed in an opening (71B) in the solder resist layer (70B).

An opening (71AA) is formed toward a center of the solder resist layer (70A), exposing the wiring structure (20) formed on the outermost interlayer insulating layer (50G). The wiring structure (20) forms a bus line between the first IC chip (110A) and the second IC chip (110B).

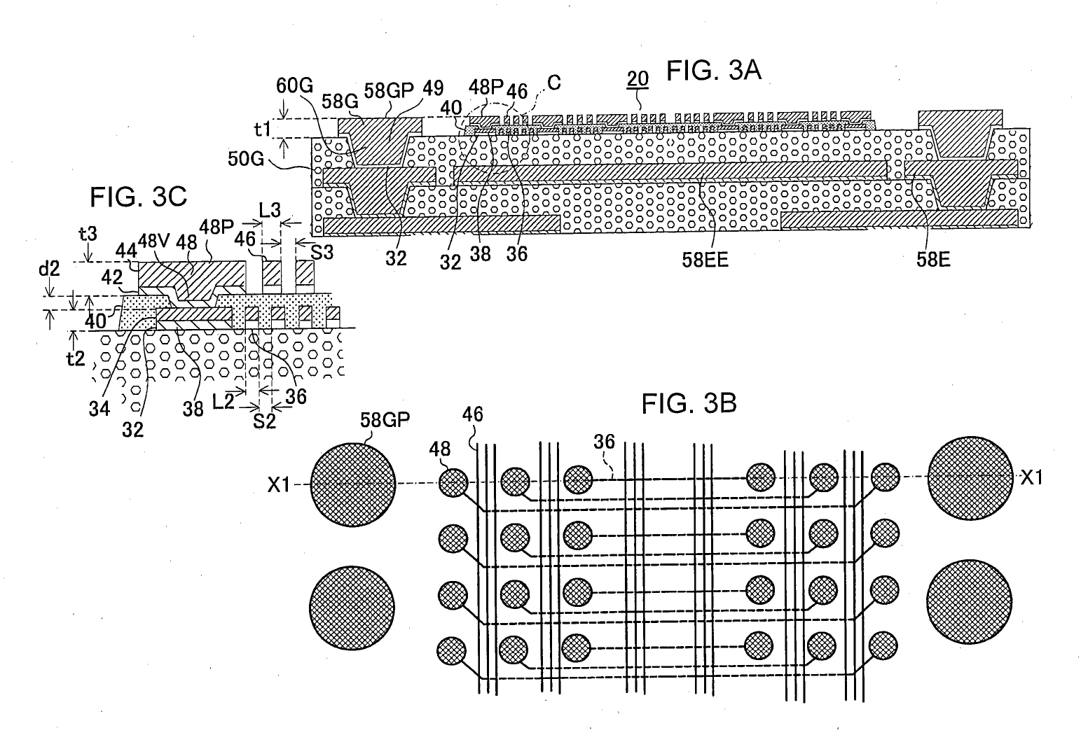

FIG. 3A is an enlarged view of the wiring structure (20) demarcated by a dashed line in FIG. 1. FIG. 3B is a plan view of the wiring structure (20), and a cross-section along a line X1-X1 in FIG. 3B corresponds to FIG. 3A. FIG. 3C is an enlarged view of a portion demarcated by an ellipse (C) in FIG. 3A.

The wiring structure (20) is formed by a second pad (38) and a second wiring line (36) formed on the outermost interlayer insulating layer (50G); a second insulating layer (40) formed on the second pad (38) and the second wiring line (36); a third pad (48P) and a third wiring line (46) formed on the second insulating layer (40); and a via conductor (48V) running through the second insulating layer (40) and connecting the second pad (38) with the third pad (48P).

The via conductor (48V) and the third wiring line (46) are formed by a seed layer (42) and an electrolysis copper plating layer (44). The second pad (38) and the second wiring line (36) are formed by a seed layer (32) and an electrolysis copper plating layer (34). The first conductor layer (58G) and the via conductor (60G) are formed by the seed layer (32) and an electrolysis copper plating layer (49). The second pad (38) and the second wiring line (36), and the first conductor layer (58G) and the via conductor (60G) include the shared seed layer (32).

A plane layer (58EE) forming a portion of the conductor layer (58E) and used as a grounding layer is formed on a layer below the outermost interlayer insulating layer (50G) forming the wiring structure (20). The second wiring line (36) takes on a microstrip line structure due to the plane layer (58EE). As a result, transmission speed of the second wiring line (36) improves.

As shown in FIG. 3A, a top surface of the first conductor layer (58G) is positioned such that the first pad (58GP) on a top surface of the via conductor (60G) and the third pad (48P) on a top surface of the via conductor (48V) are on the same plane. In other words, a height (t1) from the top surface of the interlayer insulating layer (50G) to the first pad (58GP) and the third pad (48P) is the same at 15 μm.

As shown in FIG. 3C, a height (t2) of the second pad (38) and the second wiring line (36) is between 2 and 3 pun. A height (t3) from a land of the via conductor (48V) and the top surface of the second insulating layer of the third wiring line (46) is between 4 and 6 μm. An insulation distance (d2) of the second insulating layer (40) is, as noted above, adjusted such that the first pad (58GP) of the top surface of the via conductor (60G) and the third pad (48P) on the top surface of the via conductor (48V) are on the same plane.

As shown in FIG. 2, the first terminal (114M) of the IC chip is connected to the first pad (58GP) via the first solder bump (112M). A third terminal (114S) of the IC chip is connected to the third pad (48P) via a third solder bump (112S).

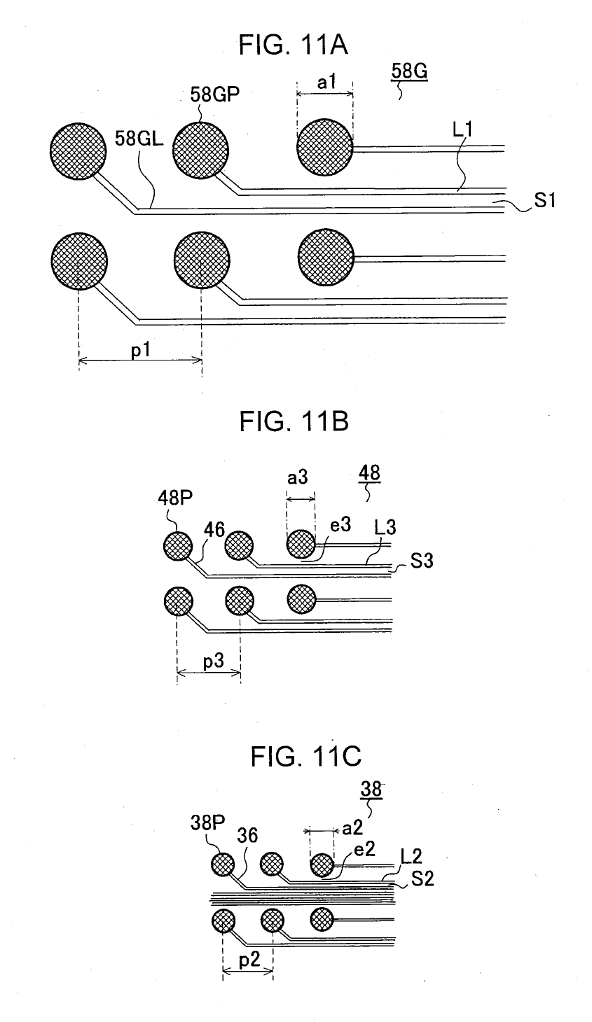

FIG. 11A is a plan view of the first pad (58GP) and the first wiring line (58GL) forming the first conductor layer (58G); FIG. 11B is a plan view of the third pad (48P) and the third wiring line (46) forming the third conductor layer (48); and FIG. 11C is a plan view of the second pad (38P) and the second wiring line (36) forming the second conductor layer (38). As shown in FIG. 11A, a diameter (a1) of the first pad (58GP) is between 50 and 100 μm, and a pitch (p1) is between 100 and 150 μm. A line width (L1) of the first wiring line (58GL) is between 10 and 20 μm, and a spacing width (S1) is between 10 and 20 μm. As shown in FIG. 11B, a diameter (a3) of the third pad (48P) is between 20 and 30 μm, and a pitch (p3) is between 40 and 60 μm. A line length (L3) of the third wiring line (46) is 3 μm, and a spacing width (S3) is 3 μm. In addition, a minimum interval (e3) between the third pad (48P) and the wiring line (46) is 5 μm. As shown in FIG. 11C, a diameter (a2) of the second pad (43P) is between 15 and 25 μm, and a pitch (p2) is between 40 and 60 μm. A line length (L2) of the second wiring line (36) is 2 μm, and a spacing width (S2) is 2 μm. In addition, a minimum interval (e2) between the second pad (38P) and the wiring line (36) is 3 μm.

In other words, the diameter (a1) of the first pad (58GP)>the diameter (a3) of the third pad (48P)>the diameter (a2) of the second pad (88P), and the pitch (p1) of the first pad (58GP)>the pitch (p3) of the third pad (48P)> or = the pitch (p2) of the second pad (88P). In addition, the line width (L1)/the spacing (S1) of the first wiring line (58GL)>the line width (L3)/the spacing (S3) of the third wiring line (46)>the line width (L2)/the spacing (S2) of the second wiring line (36).

The third conductor layer (48), which is formed by the via conductor (48V) and the third wiring line (46), and the second conductor layer (38), which is formed by the second pad (38P) and the second wiring line (36), are not connected to the first conductor layer (58G).

Moreover, the top surface of the first pad (58G) and the top surface of the third pad (48P) are positioned so as to be on the same plane. Therefore, a connection to the IC chip installed on the first pad and the third pad is highly reliable. In addition, a combined thickness of the second conductor layer (38), the second insulating layer (40), and the third conductor layer (48) is identical to the thickness (t1) of the first conductor layer (58G). Therefore, the second conductor layer and the third conductor layer are thin. The second conductor layer and the third conductor layer can be formed at a fine pitch.

### Method for Manufacturing the First Embodiment

The printed wiring board according to the first embodiment may be a printed wiring board having a core substrate, or may be a coreless substrate. A printed wiring board having a core substrate and a manufacturing method thereof are described in JP 2007-227512A, for example. The entire contents of this publication are incorporated herein by reference. A coreless substrate and a manufacturing method thereof are described in JP 2005-236244A, for example.

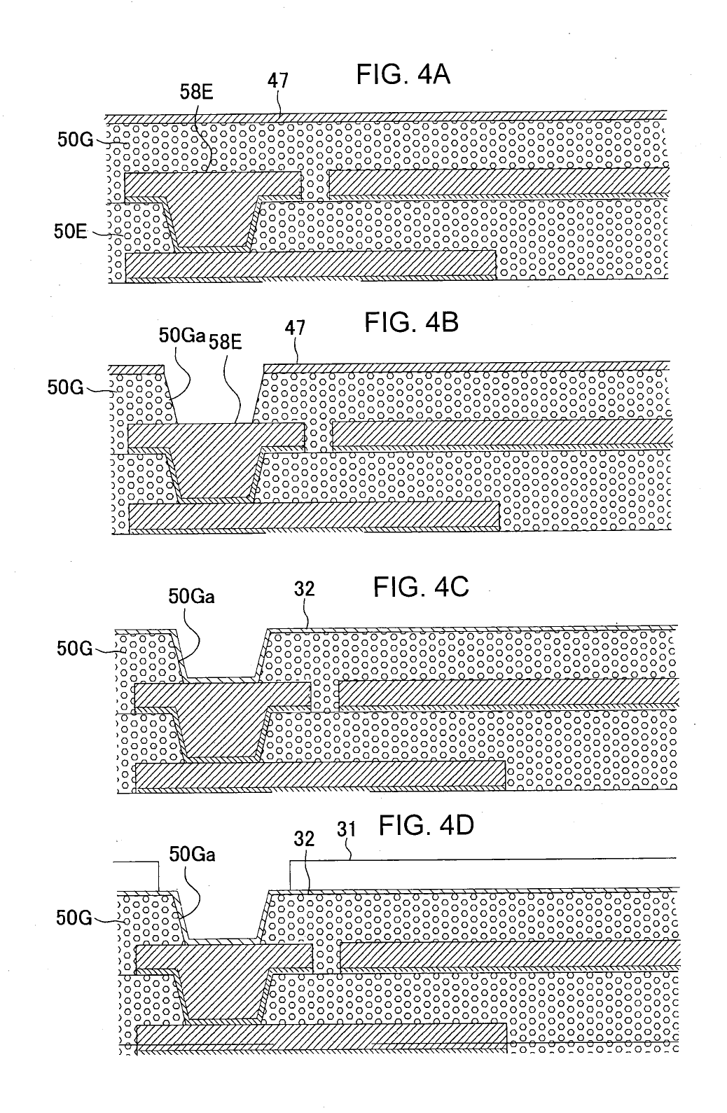

A method for manufacturing the wiring structure (20) is shown in FIG. 4A to 9C. FIG. 4A illustrates a state where the outermost resin insulating layer (first interlayer insulating layer) (50G) shown in FIG. 1 has been formed. A copper foil (47) is laminated onto the outermost resin insulating layer (50G).

A via opening (50Ga) is formed in the outermost resin insulating layer (50G) using a laser (FIG. 4B). After the copper foil is detached by etching, the seed layer (32) is formed on the outermost resin insulating layer (50G) and within the via opening (50Ga) using electroless plating or sputtering (FIG. 4C). A plating resist (31) having a predetermined pattern is formed on the seed layer (32) (FIG. 4D).

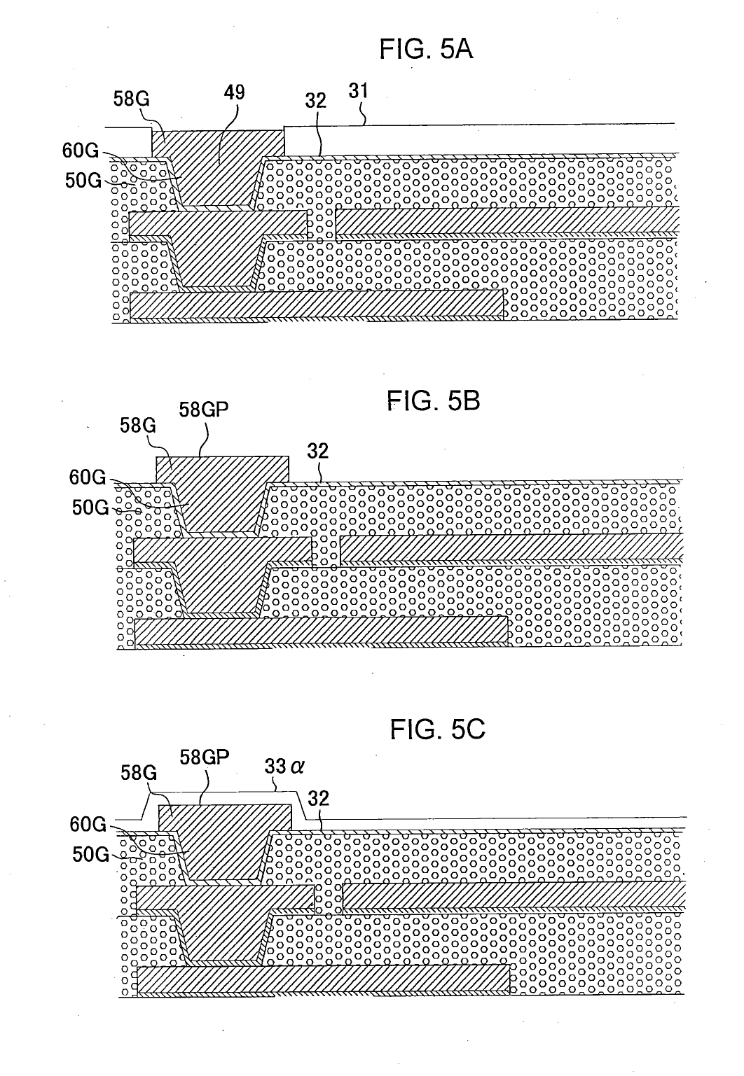

Using electrolysis copper plating, the copper plating layer (49) is formed on a portion where the plating resist (31) is not formed, and a via conductor (60G) and the first conductor layer (58G) are formed within the via opening (50Ga) (FIG. 5A). The via conductor (60G) and first conductor layer (58G) are formed by the seed layer (32) and the copper plating layer (49). The plating resist is detached (FIG. 5B). A positive plating resist fluid (33α) is applied onto the seed layer (32) and the first conductor layer without removing the seed layer (32) (FIG. 5C).

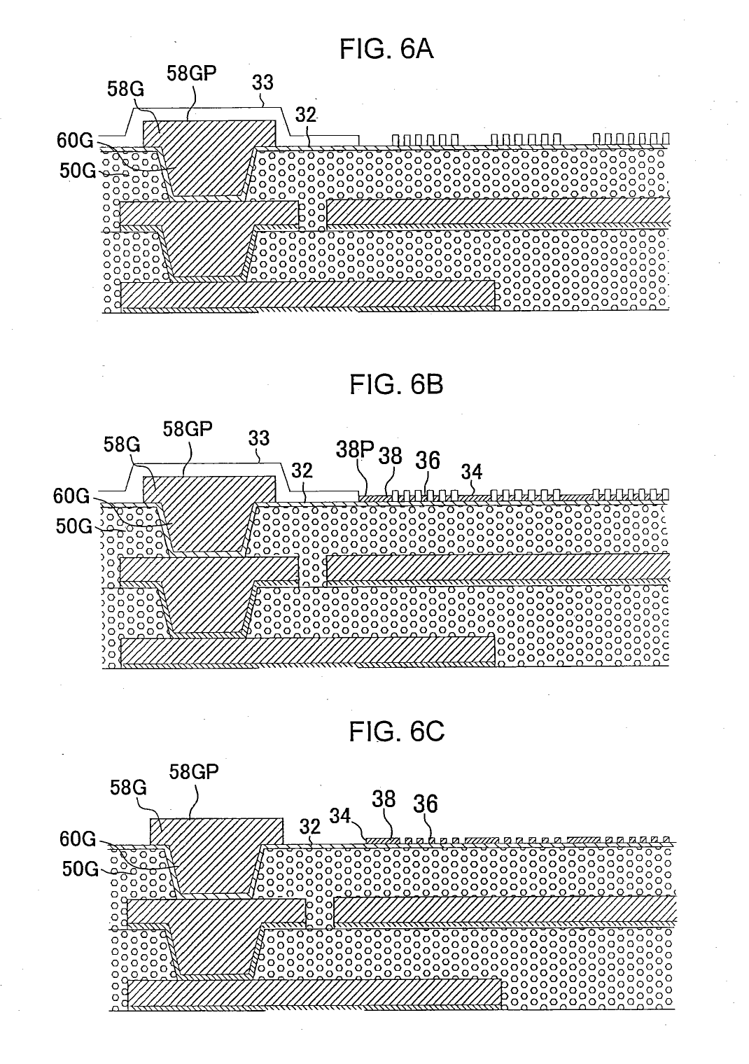

Through an exposure and development process, the plating resist (33) is formed (FIG. 6A). The pattern of the resist (33) forms the line width (L2) of 2 μm and the spacing width (S2) of 2 μm for the second wiring line, as shown in FIG. 11C. The copper plating layer (34) is formed on a portion where the plating resist (33) is not formed, and a second conductor layer (38) is formed that includes the second pad (38P) and the second wiring line (36) (FIG. 6B). The plating resist is detached (FIG. 6C).

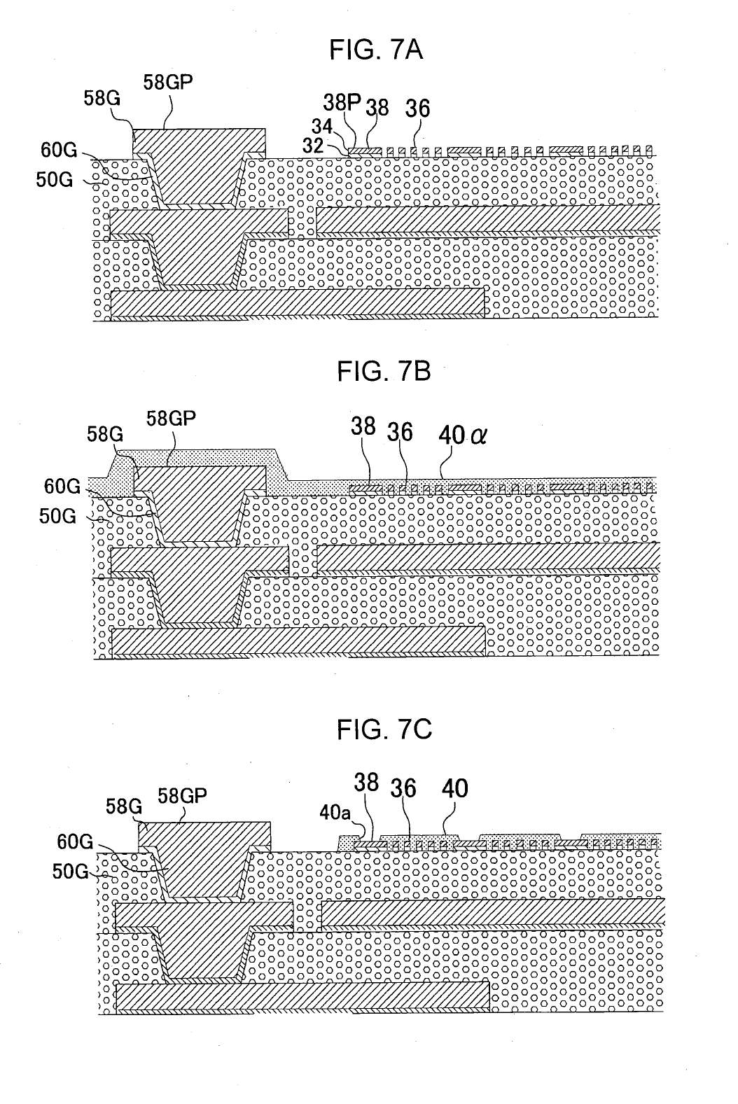

The seed layer (32) of the portion where the first conductor layer (58G) and the second conductor layer (38) are not formed is removed (FIG. 7A). A photosensitive resist fluid (40α) is applied onto the topmost interlayer resin insulating layer (50G) (FIG. 7B), and the second insulating layer (40), which includes a via opening (40a), is formed by exposure/development (FIG. 7C).

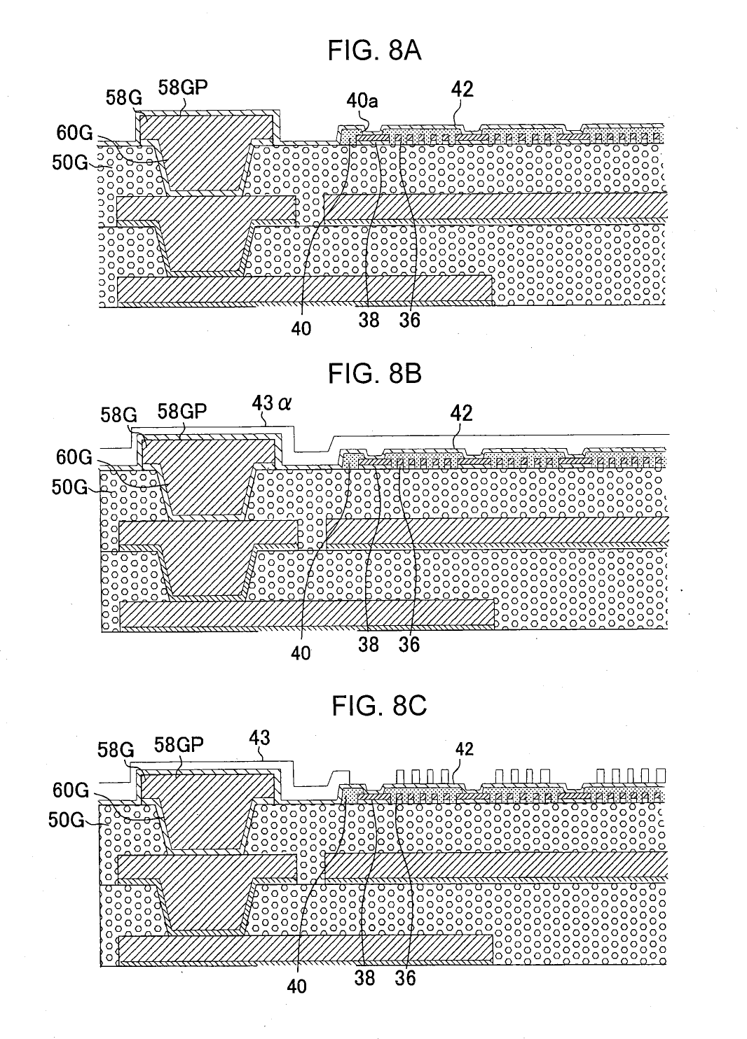

The seed layer (42) is formed on the second insulating layer (40) and within the via opening (40a) (FIG. 8A). In FIG. 8A, the seed layer (42) is formed on the first conductor layer (58G) and also on the topmost interlayer resin insulating layer (50G); however, the seed layer (42) can also be formed only on the second insulating layer (40) and within the via opening (40a). A positive plating resist fluid (43α) is applied onto the seed layer (42) (FIG. 8B). Through an exposure/development process, the plating resist (43) is formed (FIG. 8C). A pattern of the plating resist (43) is formed. The pattern of the resist (43) forms the line width (L3) of 3 μm and the spacing width (S3) of 3 μm for the third wiring line, as shown in FIG. 11B.

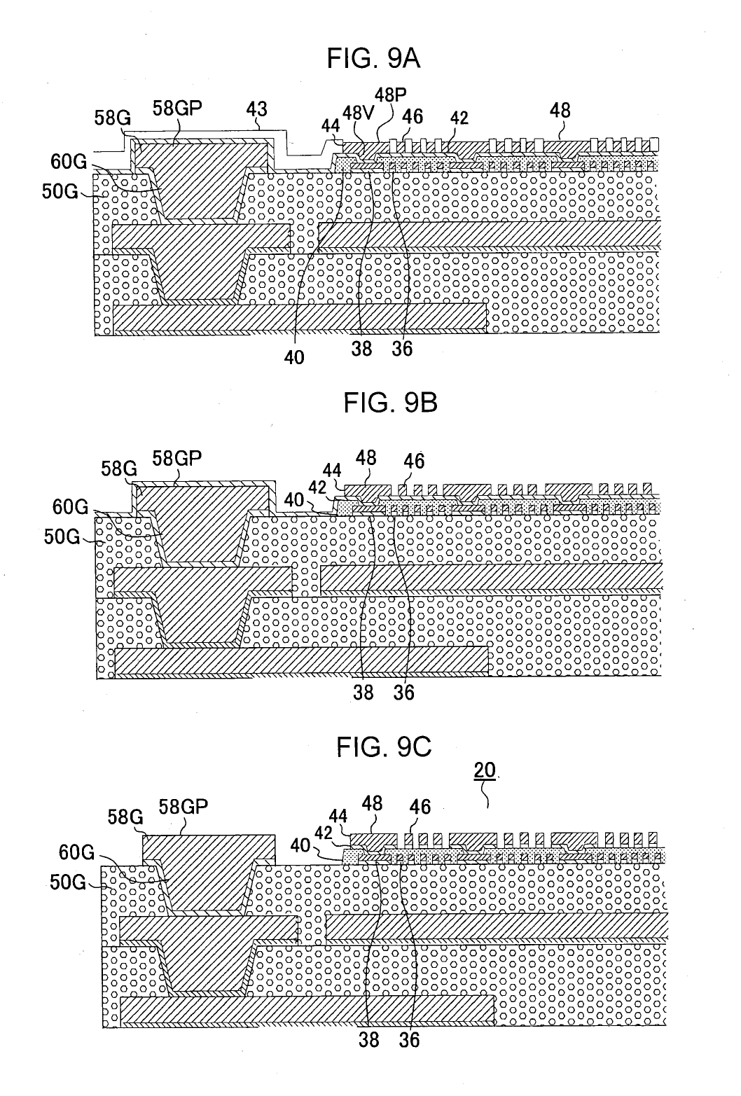

The copper plating film (44) is formed on a portion where the plating resist (43) is not formed, and the third conductor layer (48) is formed, the third conductor layer (48) including the third wiring line (46) and the via conductor (48V) having the third pad (48P) on the top surface thereof (FIG. 9A). The plating resist is detached (FIG. 9B). The seed layer (42) of the portion where the third conductor layer (48) is not formed is removed (FIG. 9C). The wiring structure (20) shown in FIG. 1 is completed.

As shown in FIG. 2, the solder resist layer (70A) that includes the opening (71A) and the opening (71AA) is formed on the build-up layer (500F), while the solder resist layer (70B) that includes the opening (71B) is formed on the build-up layer (500S). The BGA bump (76B) is formed in the opening (71B) of the solder resist layer (70B). A protective film (72) can be formed within the opening (71B). The IC chips (110A) and (110B) are installed on the printed wiring board. The first terminal (114M) of the IC chip is connected to the first pad (58GP) of the printed wiring board via the first solder bump (112M), and the third terminal (114S) of the IC chip is connected to the third pad (48P) of the printed wiring board via the third solder bump (112S).

The top surface of the first pad (58GP) and the top surface of the third pad (48P) are positioned so as to be on the same plane. Therefore, a connection to the IC chip installed on the first pad and the third pad is highly reliable. In addition, a combined thickness of the second conductor layer (38), the second insulating layer (40), and the third conductor layer (48) is identical to the thickness (t1) of the first conductor layer (58G) (see FIG. 3A). Therefore, the second conductor layer and the third conductor layer are thin, and the second conductor layer and the third conductor layer can be formed at a fine pitch.

In the printed wiring board according to the first embodiment, the second conductor layer and the third conductor layer are formed as build-up layers of the printed wiring board. Therefore, formation is easy and reliability is high.

### Second Embodiment

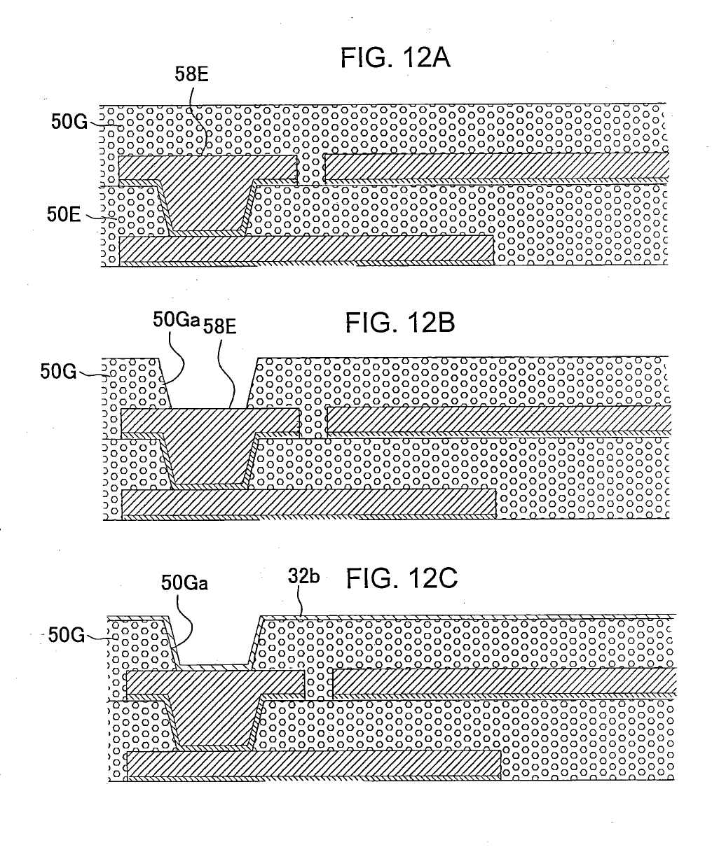

A method for manufacturing the printed wiring board (10) according to a second embodiment of the present invention is shown in FIG. 12A to 12C. FIG. 12A illustrates a state where the outermost resin insulating layer (first interlayer insulating layer) (50G) shown in FIG. 1 has been formed. A copper foil is not laminated onto the outermost resin insulating layer (50G). The surface of the resin insulating layer (50G) is not roughened.

The via opening (50Ga) is formed in the outermost resin insulating layer (50G) using a laser (FIG. 12B). Using electroless plating or Ti/Cu sputtering, a seed layer (32b) is formed on the outermost resin insulating layer (50G) and within the via opening (50Ga) (FIG. 12C). Subsequent steps are similar to those of the first embodiment, shown in FIG. 4D to 9C.

In order to achieve both a fine pitch placement and reliability of IC chips, an IC chip may be divided into multiple IC chips.

A manufacturing process to assemble the heat-resistant substrate, which has a separate structure from a printed wiring board, becomes complicated.

A printed wiring board according to an embodiment of the present invention has a high density of signal wires between multiple electronic components formed thereon, and also has high installation reliability. According to another embodiment of the present invention, a method for manufacturing the printed wiring board is provided.

A printed wiring board according to an embodiment of the present invention includes an insulating layer, a conductor layer formed on a surface of the insulating layer, and a via conductor formed through the insulating layer and connecting the conductor layer of the insulating layer to the opposite surface. The conductor layer and the insulating layer are laminated alternatingly, and the printed wiring board includes a first insulating layer, and a first conductor layer that includes first pads formed on the first insulating layer. In addition, the printed wiring board includes a wiring structure formed by a second conductor layer that includes second pads formed on the first insulating layer, a second insulating layer laminated onto the second conductor layer, a third conductor layer that includes third pads formed on the second insulating layer, and via conductors formed through the second insulating layer and connecting the second pads to the third conductor layer. The second conductor layer and third conductor layer of the wiring structure are not electrically connected to the first conductor layer.

A manufacturing method for a printed wiring board according to an embodiment of the present invention includes build-up laminating a conductor layer and an insulating layer so as to alternate the conductor layer and the insulating layer, forming an outermost insulating layer, forming a first opening for a via connection on the outermost insulating layer, forming a first seed layer on the outermost insulating layer and within the first opening, forming a first plating resist in a portion on the outermost insulating layer where the first conductor layer is not formed and which includes a formation location of a wiring structure, forming a via conductor within the first opening and forming the first conductor layer using electroplating; detaching the first plating resist, forming a second plating resist in a portion on the outermost insulating layer where the second conductor layer is not formed; forming the second conductor layer using electroplating, detaching the second plating resist, removing the first seed layer in the portion where the first conductor layer and second conductor layer are not formed, forming the second insulating layer having a second opening on the outermost insulating layer and the second conductor layer, forming a second seed layer on the second insulating layer and within the second opening, forming a third plating resist in a portion on the second insulating layer where the third conductor layer is not formed, forming a via conductor within the second opening using electroplating and forming the third conductor layer such that a top surface of the third conductor layer and a top surface of the first conductor layer are positioned on the same plane; detaching the third plating resist, and removing the second seed layer in the portion where the third conductor layer is not formed.

A printed wiring board according to an embodiment of the present invention has two conductor layers, the second conductor layer and the third conductor layer, formed on the outermost interlayer insulating layer on which the first conductor layer is formed. Therefore, the second conductor layer and the third conductor layer forming signal wires between multiple IC chips can be formed at a fine pitch. The second conductor layer and the third conductor layer can be formed as a build-up layer of the printed wiring board. Therefore, formation is easy and reliability is high.

Moreover, the top surfaces of the first pads and the top surfaces of the third pads on the second insulating layer are positioned so as to be on the same plane. Therefore, a connection to the IC chip installed on the first pad and the third pad is highly reliable. In addition, a combined thickness of the second conductor layer, the second insulating layer, and the third conductor layer is identical to a thickness of the first conductor layer. Therefore, the second conductor layer and the third conductor layer are thin, and can be formed at a fine pitch.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a first insulating layer;
a first conductor layer formed on a surface of the first insulating layer and comprising a plurality of first pads; and
a wiring structure comprising a second conductor layer formed on the first insulating layer, a second insulating layer laminated on the second conductor layer, a third conductor layer formed on the second insulating layer, and a plurality of via conductors formed through the second insulating layer,
wherein the second conductor layer includes a plurality of second pads formed on the first insulating layer, the third conductor layer includes a plurality of third pads formed on the second insulating layer, the plurality of via conductors is positioned such that the plurality of via conductors is connecting the plurality of second pads and the third conductor layer, and the wiring structure is formed such that the second conductor layer and third conductor layer are not electrically connected to the first conductor layer.

2. A printed wiring board according to claim 1, wherein the first insulating layer forms an outermost interlayer insulating layer.

3. A printed wiring board according to claim 1, wherein the plurality of third pads is formed on the second insulating layer such that upper surfaces of the third pads and upper surfaces of the first pads are positioned on a same plane.

4. A printed wiring board according to claim 1, wherein the second conductor layer of the wiring structure is formed such that the first conductor layer and the second conductor layer have a shared seed layer formed on the first insulating layer.

5. A printed wiring board according to claim 4, wherein the seed layer of the first conductor layer and the second conductor layer comprises one of an electroless Cu plated layer and a Ti/Cu sputtered layer.

6. A printed wiring board according to claim 1, wherein the second insulating layer comprises a photosensitive resin material.

7. A printed wiring board according to claim 1, further comprising:
a lower insulating layer on which the first insulating layer is formed; and
a plane layer formed on the lower insulating layer such that the plane layer is positioned directly across the wiring structure on the first insulating layer.

8. A printed wiring board according to claim 7, wherein the plane layer forms a grounding layer.

9. A printed wiring board according to claim 1, wherein the plurality of third pads is positioned to mount a first IC chip and a second IC chip on the first insulating layer, and the second conductor layer and the third conductor layer form a bus line structure between the first IC chip and the second IC chip.

10. A printed wiring board according to claim 1, wherein the plurality of first pads is positioned in an outer portion on the surface of the first insulating layer, and the plurality of third pads is positioned in an inner portion on the surface of the first insulating layer.

11. A printed wiring board according to claim 1, wherein the third conductor layer includes a plurality of wiring lines formed such that an insulating distance between the plurality of wiring lines and the plurality of third pads is greater than an insulating distance between the wiring lines.

12. A printed wiring board according to claim 1, wherein the plurality of third pads is formed such that the plurality of third pads has a thickness which is greater than a thickness of the plurality of second pads.

13. A printed wiring board according to claim 1, wherein the third conductor layer includes a plurality of wiring lines, and the second conductor layer includes a plurality of wiring lines formed such that the plurality of wiring lines of the second conductor layer has a line width which is smaller than a line width of the plurality of wiring lines of the third conductor layer.

14. A printed wiring board according to claim 13, wherein the first conductor layer includes a plurality of wiring lines, and the third conductor layer includes the plurality of wiring lines formed such that the plurality of wiring lines of the third conductor layer has a line width which is smaller than a line width of the plurality of wiring lines of the first conductor layer.

15. A printed wiring board according to claim 1, wherein the plurality of first pads is formed on the first insulating layer such that a pitch of the first pads is greater than a pitch of the third pads.

16. A manufacturing method for a printed wiring board, comprising:
forming a first conductor layer on a surface of a first insulating layer; and
forming a wiring structure on the surface of the first insulating layer such that the wiring structure has a second conductor layer on the first insulating layer, a second insulating layer laminated on the second conductor layer, a third conductor layer formed on the second insulating layer, and a plurality of via conductors formed through the second insulating layer,
wherein the second conductor layer is formed to include a plurality of second pads on the first insulating layer, the third conductor layer is formed to include a plurality of third pads formed on the second insulating layer, the plurality of via conductors is positioned such that the plurality of via conductors is connecting the plurality of second pads and the third conductor layer, and the wiring structure is formed such that the second conductor layer and third conductor layer are not electrically connected to the first conductor layer.

17. A manufacturing method for a printed wiring board according to claim 16, wherein the first conductor layer and the second conductor layer are formed such that a first seed layer is formed on the first insulating layer, a first plating resist is formed on the first insulating layer to cover a portion where the first conductor layer is not to be formed and a portion where the wiring structure is to be formed, electroplating is applied to form the first conductor layer, the first plating resist is removed, a second plating resist is formed on the first insulating layer to cover a portion where the second conductor layer is not to be formed, electroplating is applied to form the second conductor layer, the second plating resist is removed, and the first seed layer is removed from the first insulating layer in the portion where the first conductor layer and second conductor layer are not to be formed.

18. A manufacturing method for a printed wiring board according to claim 17, wherein the forming of the wiring structure includes forming a plurality of openings in the second insulating layer, forming a second seed layer on the second insulating layer and in the openings in the second insulating layer, forming a third plating resist on the second insulating layer in a portion where the third conductor layer is not to be formed, applying electroplating on the second seed layer such that the third conductor layer is formed on the second insulating layer and the via conductors are formed in the openings in the second insulating layer, removing the third plating resist from the second seed layer, and removing the second seed layer from the second insulating layer in the portion where the third conductor layer is not to be formed.

19. A manufacturing method for a printed wiring board according to claim 18, wherein the third conductor layer is formed such that an upper surface of the third conductor layer and an upper surface of the first conductor layer are positioned on a same plane.

20. A manufacturing method for a printed wiring board according to claim 16, wherein the first insulating layer forms an outermost interlayer insulating layer, the plurality of third pads is positioned to mount a first IC chip and a second IC chip on the first insulating layer, and the second conductor layer and the third conductor layer form a bus line structure between the first IC chip and the second IC chip.
